(19) United States
(12) Patent Application Publication
(10) Pub. No.: US 2024/0178813 A1
(43) Pub. Date: May 30, 2024

(54) MULTILAYER FILM SUBSTRATE, ACOUSTIC WAVE DEVICE, MODULE, AND METHOD FOR PRODUCING MULTILAYER FILM SUBSTRATE

(71) Applicant: Sanan Japan Technology Corporation, Tokyo (JP)

(72) Inventors: Yoshiaki Takaoka, Tokyo (JP); Shinichi Shioi, Tokyo (JP)

(73) Assignee: Sanan Japan Technology Corporation, Tokyo (JP)

(21) Appl. No.: 18/519,484

(22) Filed: Nov. 27, 2023

(30) Foreign Application Priority Data
Nov. 28, 2022 (JP) 2022-189660

(51) Int. Cl. H03H 9/02; H03H 3/08; H03H 9/05

(52) U.S. Cl. CPC H03H 9/02574; H03H 3/08; H03H 9/02559; H03H 9/0576

(57) ABSTRACT

A multilayer film substrate includes a piezoelectric substrate, a first insulating film formed on the piezoelectric substrate, a support substrate, a second insulating film formed on the support substrate, and a bonding layer formed between the first insulating film and the second insulating film. The piezoelectric substrate and the support substrate are bonded each other using the first insulating film, the second insulating film, and the bonding layer as an interlayer.

### CROSS-REFERENCE TO RELATED APPLICATION(S)

This application claims priority to Japanese Application No. 2022-189660, filed Nov. 28, 2023, which are incorporated herein by reference, in their entirety, for any purpose.

### BACKGROUND OF THE INVENTION

### Field of the Invention

The present invention relates to multilayer film substrates, acoustic wave devices, modules and method for producing multilayer film substrates.

### Background Art

It is required for acoustic wave devices, the bonding strength between a piezoelectric substrate and a support substrate is secured. For this reason, improvement of bondability between the piezoelectric substrate and the supporting substrate is desired.

### SUMMARY OF THE INVENTION

Some examples described herein may address the above-described problems. Some examples described herein may has an object to provide a multilayer film substrate, an acoustic wave device, a module, and a method for producing the multilayer film substrate which can improve bondability between a piezoelectric substrate and a support substrate.

In some examples, a multilayer film substrate includes a piezoelectric substrate, a first insulating film formed on the piezoelectric substrate, a support substrate, a second insulating film formed on the support substrate, and a bonding layer formed between the first insulating film and the second insulating film.

### BRIEF DESCRIPTION OF THE DRAWING

FIG. 1 is a longitudinal cross-sectional view of an acoustic wave device in a first embodiment.

FIG. 2 is a diagram illustrating an example of an acoustic wave element of the acoustic wave device in the first embodiment.

FIG. 3 is a longitudinal cross-sectional view of a multilayer film substrate of the acoustic wave device in the first embodiment.

FIG. 4 is a diagram for explaining a method for producing the acoustic wave device in the first embodiment of the present invention.

FIG. 5 is a diagram for explaining the method for producing the acoustic wave device in the first embodiment of the present invention.

FIG. 6 is a diagram for explaining the method for producing the acoustic wave device in the first embodiment of the present invention.

FIG. 7 is a diagram showing the variation in a resonance frequency and an antiresonance frequency relative to the thickness of a piezoelectric substrate and an interlayer of the multilayer film substrate of the acoustic wave device in the first embodiment.

FIG. 8 is a diagram showing the variation in the resonance frequency between the multilayer film substrate and a comparative example of the acoustic wave device in the first embodiment.

FIG. 9 is a diagram showing the variation in the anti-resonance frequency between the multilayer film substrate and the comparative example of the acoustic wave device in the first embodiment.

FIG. 10 is a longitudinal sectional view of a module to which the acoustic wave device in a second embodiment is applied.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### First Embodiment

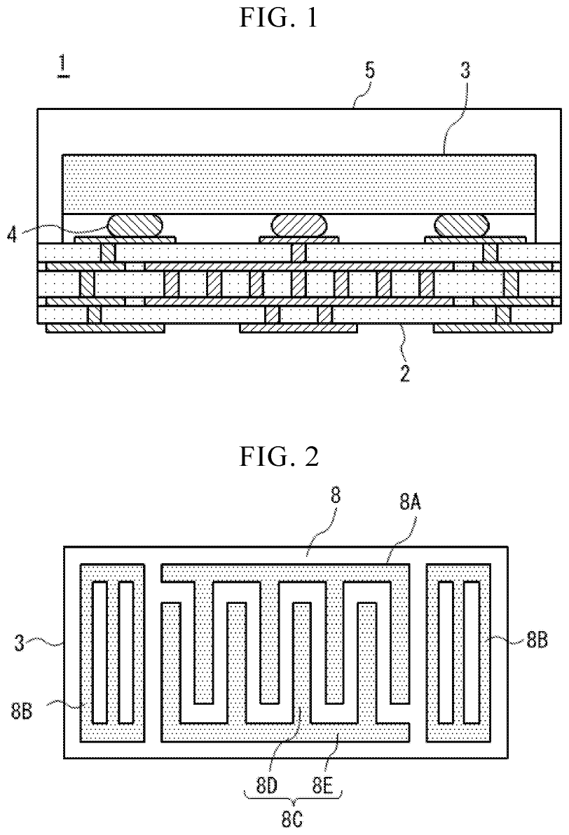

FIG. 1 is a longitudinal cross-sectional view of an acoustic wave device in the first embodiment.

FIG. 1 shows an example of the acoustic wave device that is a duplexer as an acoustic wave device 1.

As shown in FIG. 1, the acoustic wave device 1 includes a wiring substrate 2, a multilayer film substrate 3, a plurality of bumps 4, and a sealing portion 5.

For example, the wiring substrate 2 is a multilayer substrate made of resin. For example, the wiring substrate 2 is a low-temperature co-fired ceramic (Low Temperature Co-fired Ceramics: LTCC) multilayer substrate includes a plurality of dielectric layers.

The multilayer film substrate 3 includes a substrate on which is an acoustic wave element (not shown in FIG. 1). For example, a receiving filter and a transmitting filter are formed on the main surface (the lower surface in FIG. 1) of the multilayer film substrate 3.

The receiving filter is formed such that an electrical signal of a desired frequency band can pass through. For example, the reception filter is a ladder-type filter including a plurality of series resonators and a plurality of parallel resonators.

The transmitting filter is formed such that an electrical signal of a desired frequency band can pass through. For example, the transmitting filter is a ladder-type filter including a plurality of series resonators and a plurality of parallel resonators.

A plurality of bumps 4 are electrically connected to a wiring formed on the main surface (the upper surface in FIG. 1) of the wiring substrate 2 and a wiring formed on the main surface of the multilayer film substrate 3.

The sealing portion 5 is formed so as to cover the multilayer film substrate 3. The sealing portion 5 seals the multilayer film substrate 3 together with the wiring substrate 2. In some examples, the sealing portion 5 is formed of an insulator such as a synthetic resin. In some examples, the sealing portion 5 is made of metal. In some examples, the sealing portion 5 is formed of an insulating layer and a metal layer.

When the sealing portion 5 is formed of a synthetic resin, the synthetic resin is an epoxy resin, polyimide, or the like. Preferably, the sealing portion 5 is formed of an epoxy resin using a low temperature curing process.

Next, an example of the acoustic wave element will be described with reference to FIG. 2. FIG. 2 is a diagram illustrating the example of the acoustic wave element of the acoustic wave device in the first embodiment.

In the example of FIG. 2, the acoustic wave element is a surface acoustic wave resonator. As shown in FIG. 2, an IDT (Interdigital Transducer) 8A and a pair of reflectors 8B are formed on the main surface of the multilayer film substrate 3. The IDT 8A and the pair of reflectors 8B are provided so as to excite the surface acoustic wave.

In some examples, the IDT 8A and the pair of reflectors 8B are formed of an alloy of aluminum and copper. In some examples, the IDT 8A and the pair of reflectors 8B are formed of suitable metals such as titanium, palladium, silver, and the like, or alloys thereof. In some examples, the IDT 8A and the pair of reflectors 8B are formed by a laminated metal film in which a plurality of metal layers are laminated. In some examples, the thickness of the IDT 8A and the pair of reflectors 8B is 150 nm to 400 nm.

The IDT 8A includes a pair of comb-shaped electrodes 8C. The pair of comb-shaped electrodes 8C are opposed to each other. The comb-shaped electrodes 8C includes a plurality of electrode fingers 8D and a bus bar 8E. The plurality of electrode fingers 8D are arranged in the longitudinal direction. The bus bar 8E connects the plurality of electrode fingers 8D.

One of the pair of reflectors 8B adjoins one side of the IDT 8A. The other of the pair of reflectors 8B adjoins the other side of the IDT 8A.

Next, the configuration of the multilayer film substrate 3 will be described with reference to FIG. 3. FIG. 3 is a longitudinal cross-sectional view of the multilayer film substrate of the acoustic wave device in the first embodiment.

As shown in FIG. 3, the multilayer film substrate 3 includes a piezoelectric substrate 3A, a first insulating film 3B, a support substrate 3 C, a second insulating film 3D, and a bonding layer 3E.

For example, the piezoelectric substrate 3A is formed of lithium tantalate. For example, the first insulating film 3B is formed of silicon dioxide. The first insulating film 3B is formed on the piezoelectric substrate 3A (the lower surface of the piezoelectric substrate 3A in FIG. 3). For example, the support substrate 3C is formed of spinel. For example, the second insulating film 3D is formed of silicon dioxide. The second insulating film 3D is formed on the support substrate 3C (the upper surface of the support substrate 3C in FIG. 3). For example, the bonding layer 3E is formed of silicon. The bonding layer 3E is formed between the first insulating film 3B and the second insulating film 3D. In FIG. 3, the piezoelectric substrate 3A and the support substrate 3C are bonded to each other using the first insulating film 3B, the second insulating film 3D, and the bonding layer 3E as an interlayer.

The thickness of the piezoelectric substrate 3A is set to be about 1000 nm in the present embodiment. The thickness of the bonding layer 3E is set to be 0.1% or more and 5% or less of the thickness of the piezoelectric substrate 3A. For example, the thickness of the bonding layer 3E is set to about 8 nm. The sum of the thicknesses of the first insulating film 3B, the second insulating film 3D, and the bonding layer 3E is set to be equal to or less than half the thickness of the piezoelectric substrate 3A. The sum of the thickness of the first insulating film 3B and the second insulating film 3D and the bonding layer 3E is set to be 0.06λ or more and 0.075λ or less when the wavelength of the acoustic wave is λ. The first insulating film 3B is set to be thicker than the second insulating film 3D.

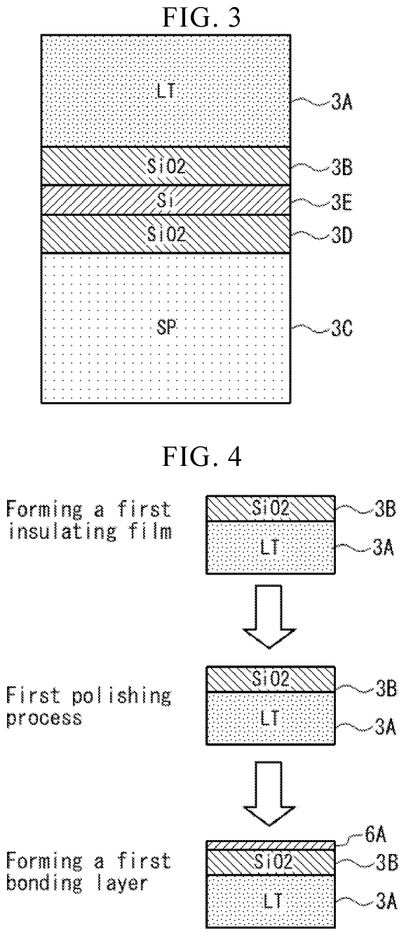

Next, a method for producing the multilayer film substrate 3 will be described with reference to FIG. 4 to FIG. 6.

FIG. 4 to FIG. 6 are diagrams for explaining the method for producing the acoustic wave device according to the first embodiment.

As shown in FIG. 4, the first insulating film 3B is formed on the piezoelectric substrate 3A (the upper surface of the piezoelectric substrate 3A in FIG. 4) by a thermal oxidation method or the like in a first insulating film forming process. In this case, the thickness of the first insulating film 3B is formed to be between 50 nm and 200 nm. After that a first polishing process is performed. The surface of the first insulating film 3B (the upper surface of the first insulating film 3B in FIG. 4) is smoothed by chemical mechanical polishing in the first polishing process. Thereafter, a first bonding layer forming process is performed. In the first bonding layer forming process, silicon as a first bonding layer 6A is formed on the first insulating film 3B (the upper surface of the first insulating film 3B in FIG. 4). In this case, the first bonding layer 6A is formed to have the thickness of about 4 nm.

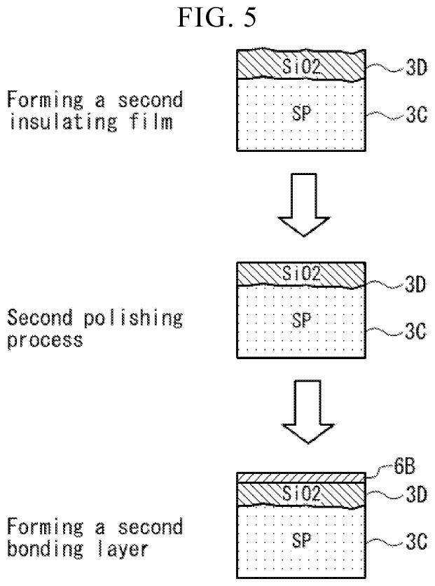

As shown in FIG. 5, the second insulating film 3D is formed on the support substrate 3C (the upper surface of the support substrate 3C in FIG. 5) by the thermal oxidation method or the like in a second insulating film forming process. In this case, the second insulating film 3D is formed to have the thickness of 50 mm to 200 nm. Thereafter, a second polishing process is performed. The surface of the second insulating film 3D (the upper surface of the second insulating film 3D in FIG. 5) is smoothed by chemical mechanical polishing in the second polishing process. Thereafter, a second bonding layer forming process is performed. In the second bonding layer forming process, a film made of silicon as a second bonding layer 6B is formed on the second insulating film 3D (the upper surface of the second insulating film 3D in FIG. 5). In this case, the second bonding layers 6B are formed to have the thickness of about 4 nm.

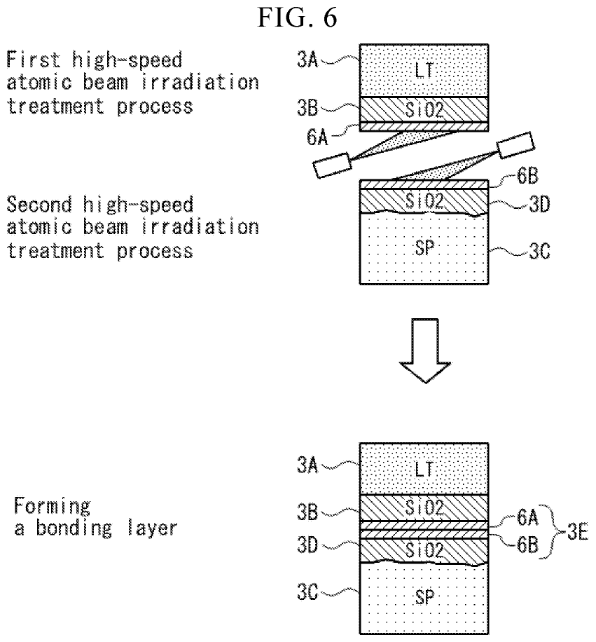

The step of FIG. 6 is performed after the steps of FIG. 4 and FIG. 5 are performed. As shown in FIG. 6, firstly, a first high-speed atomic beam irradiation treatment process and a second high-speed atomic beam irradiation treatment process are performed. The surface of the first bonding layer 6A (the lower surface of the first bonding layer 6A in FIG. 6) is subjected to the high-speed atomic beam irradiation treatment in the first high-speed atomic beam irradiation treatment process. The surface of the second bonding layer 6B (the upper surface of the second bonding layer 6B in FIG. 6) is subjected to the high-speed atomic beam irradiation treatment in the second high-speed atomic beam irradiation treatment process.

Thereafter, a bonding layer forming process is performed. The first bonding layer 6A and the second bonding layer 6B are directly bonded to each other. This forms the bonding layers 3E in the bonding layer forming process.

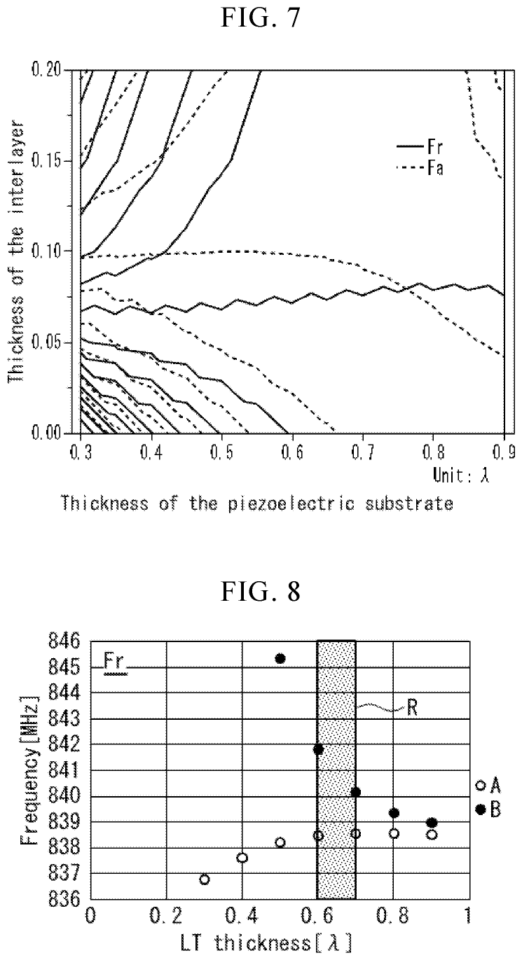

Next, a first example of variation between a resonance frequency and an anti-resonance frequency will be described with reference to FIG. 7. FIG. 7 is a diagram showing the variation in the resonance frequency and the antiresonance frequency relative to the thickness of the piezoelectric substrate and the interlayer of the multilayer film substrate of the acoustic wave device in the first embodiment.

In FIG. 7, the horizontal axis represents the thickness of the piezoelectric substrate 3A normalized to the wave length λ of the acoustic wave. The vertical axis represents the thickness of the interlayer normalized to the wavelength λ of the acoustic wave. The solid lines indicate the resonant frequency Fr. The region surrounded by the adjoining solid line is the region in which the variation of the resonant frequency Fr falls within the range of 3.5 MHz. The dashed lines indicate the anti-resonant frequency Fa. The region surrounded by the adjoining dashed line is the region in which the variation of the anti-resonance frequency Fa falls within the range of 3.5 MHz.

As shown in FIG. 7, when the design value of the thickness of the piezoelectric substrate 3A is 0.7λ for example, there is few variation in the resonance frequency Fr and the anti-resonance frequency Fa under the condition that the thickness of the interlayer is 0.06λ or more and 0.075λ or less, even though there is variation in the actual thickness of the piezoelectric substrate 3A. For example, when the design value of the thickness of the piezoelectric substrate 3A is 0.5λ, under the condition that the thickness of the interlayer is about 0.1λ, even though there is variation in the actual thickness of the piezoelectric substrate 3A, the resonant frequency Fr hardly varies.

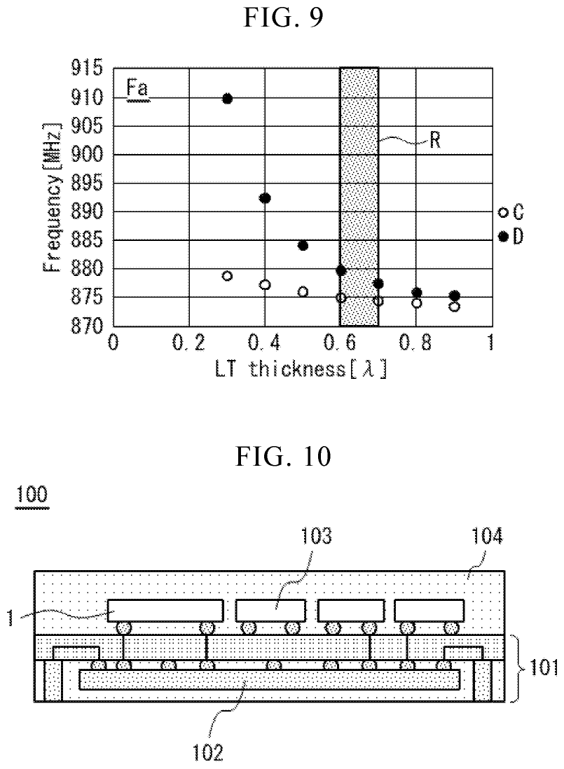

Next, a second example of variation between the resonance frequency and the anti-resonance frequency will be described with reference to FIG. 8 and FIG. 9. FIG. 8 is a diagram showing the variation in the resonance frequency between the multilayer film substrate and a comparative example of the acoustic wave device in the first embodiment. FIG. 9 is a diagram showing the variation in the anti-resonance frequency between the multilayer film substrate and the comparative example of the acoustic wave device in the first embodiment.

In FIG. 8 and FIG. 9 the horizontal axis represents the thickness of the piezoelectric substrate 3A normalized to the wave length λ of the acoustic wave. The vertical axis represents the frequency. R indicates the region where the thickness of the piezoelectric substrate 3A ranges from 0.58λ (2.7μ) to 0.71λ (3.3μ). A represents the resonance frequency of the multilayer film substrate 3 when the interlayer is 0.07λ in FIG. 8. B represents the resonant frequency of the comparative example in which the piezoelectric substrate 3A and the support substrate 3C are directly bonded to each other. C shows the variation of the anti-resonance frequency in the multilayer film substrate 3 when the interlayer is 0.07λ in FIG. 9. D shows the variation of the anti-resonance frequency in the comparative example in which the piezoelectric substrate 3A and the support substrate 3C are directly bonded to each other.

In the region R of FIG. 8, the variation of the resonant frequency B of the comparative example is 2.15 MHz. On the other hand, the variation of the resonant frequency A of the multilayer film substrate 3 is 0.13 MHz. As described above, the variation of the resonance frequency A of the multilayer film substrate 3 is considerably smaller than the variation of the resonance frequency B of the comparative example.

In the region R of FIG. 9, the variation of the anti-resonance frequency D of the comparative example is 3.10 MHz. On the other hand, the variation of the anti-resonant frequency C of the multilayer film substrate 3 is 0.71 MHz. As described above, the variation of the anti-resonance frequency C of the multilayer film substrate 3 is considerably smaller than the variation of the anti-resonance frequency D of the comparative example.

According to the first embodiment described above, the piezoelectric substrate 3A and the support substrate 3C are bonded to each other using the first insulating film 3B, the second insulating film 3D, and the bonding layer 3E as an interlayer. This improves bondability between the piezoelectric substrate 3A and the support substrate 3C.

The thickness of the bonding layer 3E is 0.1% or more and 5% or less of the thickness of the piezoelectric substrate 3A. When the thickness of the bonding layer 3E falls within this range, it has little effect acoustically the filter properties. This improves the bondability between the piezoelectric substrate 3A and the support substrate 3C while maintaining the performance as the acoustic wave device 1.

For example, the thickness of the piezoelectric board 3A is set to about 3.0 μm in Band 8. The sum of the thicknesses of the first insulating film 3B and the second insulating film 3D is set to about 300 nm. For example, the thickness of the piezoelectric substrate 3A is set to about 1.5 μm in Band 3. The sum of the thicknesses of the first insulating film 3B and the second insulating film 3D is set to about 150 nm. When the thickness of the bonding layer 3E is appropriately set in accordance with these thicknesses, the bondability between the piezoelectric substrate 3A and the support substrate 3C can be improved while maintaining the performance as the acoustic wave device 1.

The sum of the thicknesses of the first insulating film 3B, the second insulating film 3D, and the bonding layer 3E is equal to or less than half the thickness of the piezoelectric substrate 3A. This improve the bondability between the piezoelectric substrate 3A and the support substrate 3C while maintaining the performance as the acoustic wave device 1.

Further, the sum of the thickness of the first insulating film 3B and the second insulating film 3D and the bonding layer 3E is 0.06λ or more and 0.075λ or less when the acoustic wave length is λ. This improves the bondability between the piezoelectric substrate 3A and the support substrate 3C while suppressing the variation in the resonant frequency of the acoustic wave device 1, even when there is variation in the thickness of the piezoelectric substrate 3A.

The surface of the support substrate 3C is rougher than the surface of the piezoelectric substrate 3A. Therefore, the contact area of the support substrate 3C and the second insulating film 3D is larger than the contact area of the piezoelectric substrate 3A and the first insulating film 3B. Consequently, the bondability between the support substrate 3C and the second insulating film 3D can be improved.

The first insulating film 3B is thicker than the second insulating film 3D. This improves the bondability between the piezoelectric substrate 3A and the support substrate 3C while maintaining the isolation property of the piezoelectric substrate 3A.

Further, the piezoelectric substrate 3A is formed of lithium tantalate. The support substrate 3C is formed of spinel. Therefore, even when there is concern about the bonding strength with lithium tantalate because the surface of the spinel is rough, the bondability between lithium tantalate and the spinel can be improved.

The bonding layer 3E is formed by the high-speed atomic beam irradiating treatment. This makes the bonding layers 3E thin.

### Second Embodiment

FIG. 10 is a longitudinal sectional view of a module to which the acoustic wave device according to the second embodiment is applied. The same reference numerals denote the same or corresponding elements in the embodiment 1 first embodiment, details of which are not explained herein.

In FIG. 10, a module 100 includes a wiring substrate 101, an integrated circuit component 102, the acoustic wave device 1, an inductor 103, and a sealing portion 104.

The wiring substrate 101 is equivalent to the wiring substrate 2 of the first embodiment.

Although not shown, the integrated circuit component 102 is mounted inside the wiring substrate 101. The integrated circuit component 102 includes a switching circuit and a low noise amplifier.

The acoustic wave device 1 is mounted on the main surface of the wiring substrate 101.

The inductor 103 is mounted on the main surface of the wiring substrate 101. The inductor 103 is implemented for impedance matching. For example, the inductor 103 is Integrated Passive Device (IPD).

The sealing portion 104 seals a plurality of electronic components including the acoustic wave device 1.

According to the second embodiment described above, the module 100 includes the acoustic wave device 1. This can realize the module 100 including the acoustic wave device 1 with high heat dissipation.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners.

Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is claimed is:

1. A multilayer film substrate comprising:
a piezoelectric substrate;
a first insulating film formed on the piezoelectric substrate;
a support substrate;
a second insulating film formed on the support substrate; and
a bonding layer formed between the first insulating film and the second insulating film.

2. The multilayer film substrate according to claim 1,
wherein a thickness of the bonding layer is 0.1% or more and 5% or less of a thickness of the piezoelectric substrate.

3. The multilayer film substrate according to claim 1,
wherein a sum of a thickness of the first insulating film and the second insulting film and the bonding layer is equal to or less than half of a thickness of the piezoelectric substrate.

4. The multilayer film substrate according to claim 1,
wherein a sum of the thickness of the first insulating film and the second insulting film and the bonding layer is 0.06λ or more and 0.075λ or less when the acoustic wave length is A.

5. The multilayer film substrate according to claim 1,
wherein a contact area of the support substrate and the second insulating film is larger than a contact area of the piezoelectric substrate and the first insulating film.

6. The multilayer film substrate according to claim 1,
wherein the first insulting film is thicker than the second insulting film.

7. The multilayer film substrate according to claim 1,
wherein the piezoelectric substrate is formed of lithium tantalite.

8. The multilayer film substrate according to claim 1,
wherein the support substrate is formed of spinel.

9. An acoustic device comprising:
the multilayer film substrate according to claim 1; and
a plurality of acoustic wave elements formed on the multilayer film substrate.

10. A module comprising the acoustic wave device according to claim 9.

11. A method for producing a multilayer film substrate, the method comprising:
a step of forming a first insulting film on a piezoelectric substrate;
a step of forming a second insulting film on a support substrate;
a step of forming a first bonding layer on the first insulting film;
a step of forming a second bonding layer on the second insulting film; and
a step of forming a bonding layer to bond the first bonding layer to the second bonding layer.

12. The method for producing the multilayer film substrate according to claim 11, the method further comprising:
a step of a treatment with a first high-speed atomic beam irradiation to treat a surface of the first bonding layer with the first high-speed atomic beam irradiation;
a step of a treatment with a second high-speed atomic beam irradiation to treat a surface of the second bonding layer with the second high-speed atomic beam irradiation;
wherein the step of forming the bonding layer is performed after the steps of the treatment with the first high-speed atomic beam irradiation and the treatment with the second high-speed atomic beam irradiation.
